(19) United States
(12) Patent Application Publication
(10) Pub. No.: US 2006/0234090 A1
(43) Pub. Date: Oct. 19, 2006

(54) Magnetic recording medium and manufacturing method of the same

(75) Inventors: Kenichi Moriwaki, Kanagawa (JP); Kazuyuki Usuki, Kanagawa (JP); Shiho Kamisawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/395,300

(22) Filed: Apr. 3, 2006

(30) Foreign Application Priority Data
Apr. 1, 2005 (JP) P-2005-106382

(51) Int. Cl. G11B 5/65; B05D 5/12; C23C 16/00

(52) U.S. Cl. 428/836; 427/127; 427/248.1

(57) ABSTRACT

A magnetic recording medium comprising: a support; an under layer comprising at least one of a metal and an alloy; and a granular magnetic layer comprising ferromagnetic metal particles and a nonmagnetic oxide, wherein the magnetic recording medium has a surface resistivity of from 1 to 100 Ω/□.

### FIELD OF THE INVENTION

The present invention relates to a metal thin film type magnetic recording medium and a manufacturing method of the same.

### BACKGROUND OF THE INVENTION

With the spread of the Internet in recent years, the use form of the computer has been changed, e.g., to the form of processing a great volume of motion picture data and sound data with a personal computer. Along with such a trend, the storage capacity required of the magnetic recording media, such as hard discs, has increased.

In a hard disc apparatus, a magnetic head slightly floats from the surface of a magnetic disc with the rotation of the magnetic disc, and magnetic recording is done by non-contact recording system. This mechanism prevents the magnetic disc from breaking by the touch of the magnetic head and the magnetic disc. With the increase of the density of magnetic recording, the flying height of a magnetic head is gradually decreased, and now the flying height of from 10 to 20 nm has been realized by the use of a magnetic disc comprising a specularly polished hyper-smooth glass support having provided thereon a magnetic recording layer and the like. In a magnetic recording medium, a CoPtCr series magnetic layer/a Cr under layer are generally used, and the direction of easy magnetization of the CoPtCr series magnetic layer is controlled in the direction of in-plane of the film by the Cr under layer by increasing the temperature as high as 200 to 500° C. Further, the segregation of Cr in the CoPtCr series magnetic layer is accelerated and the magnetic domain in the magnetic layer is separated. The areal recording density and the recording capacity of hard disc drive have markedly increased during the past few years by technological innovation, e.g., the flying height reduction of a head, the improvement of the structure of a head, and the improvement of the recording film of a disc.

However, when a high temperature sputtering firm-forming method is used in the manufacture of a recording medium, not only the productivity is inferior but also the costs in mass production increase, so that inexpensive production is not possible.

On the other hand, with the increase of throughput of digital data, there arises a need of moving a high capacity data, such as moving data, by recording on a removable medium. However, since the support of a hard disc is made of a hard material and the distance between a head and a disc is extremely narrow as described above, there is the fear of happening of accidents by the impact during operation and entraining dusts when a hard disc is tried to be used as a removable medium such as a flexible disc and a rewritable optical disc, and so it is difficult to use a hard disc.

Flexible recording media in any form of discs and tapes take a system of contact sliding of a magnetic head and a medium, and they are excellent in removability and can be manufactured inexpensively. However, now commercially available flexible media have a structure having recording layers formed by coating magnetic powder with a polymer binder and an abrasive on a polymer film, and an evaporation type. Therefore, as compared with hard discs having a magnetic layer formed by sputtering, flexible media are inferior in high density recording characteristics.

Accordingly, a ferromagnetic metal thin film type flexible medium having a recording film formed by the same sputtering method as in hard discs is suggested. However, when it is tried to form the same magnetic layer as that of hard discs on a polymer film, the polymer film is greatly damaged by heat, so that it is difficult to put such a flexible medium to practical use. Therefore, it is also suggested to use highly heat resisting polyimide and aromatic polyamide films as polymer films, but these heat resistive films are very expensive and it is also difficult to put them to practical use. When it is tried to form a magnetic layer with cooling a polymer film so as not to give thermal damage to the polymer film, the magnetic characteristics of the magnetic layer become insufficient, thus recording density can be hardly improved.

Concerning these problems, it has come to be known that when a combination of a granular magnetic layer comprising a ferromagnetic metal alloy and a nonmagnetic oxide with an under layer comprising Cr, Ti, Ru, Re, Pt and alloys of these metals is used, almost the same magnetic characteristics as those of a medium obtained by a combination of a CoPtCr series magnetic layer with a Cr alloy under layer formed under temperature conditions as high as from 200 to 500° C. can be obtained even when formed under room temperature (refer to JP-B-8-7859 (the term “JP-B” as used herein refers to an “examined Japanese patent publication”), JP-A-7-311929 (the term “JP-A” as used herein refers to an “unexamined published Japanese patent application”), JP-A-2001-176059, JP-A-2001-291230 and JP-A-2003-99918). By the use of such a magnetic layer and an under layer capable of forming at room temperature, not only the production costs of hard discs using a glass support and an aluminum support can be widely reduced but also it is expected that the fields of application can be widened to flexible discs, magnetic tapes and magnetic sheets, since it is possible to use supports of low heat resistive polymer resins and flexible polymer films.

On the other hand, there is a problem that high magnetic characteristics can be stably obtained in conventional magnetic recording media manufactured by a high temperature process while high crystallizability cannot be obtained in the formed under layer and magnetic layer of magnetic recording media manufactured by a room temperature process and high magnetic characteristics cannot be obtained. In particular, in magnetic recording media using polymer resin and flexible film supports, the crystallizability of the under layer and the magnetic layer is low, so that magnetic characteristics are liable to lower.

As described above, demands for magnetic recording media formed by room temperature are high, and various structures have been proposed and achieved high magnetic characteristics. However, demands for magnetic recording media are severe and stable high performances and magnetic characteristics having high reliability are always required.

### SUMMARY OF THE INVENTION

Accordingly, the invention has been done in view of the prior art problems. An object of the invention is to provide an inexpensive high density magnetic recording medium having an under layer and a magnetic layer formed by room temperature and having stable high performances and high reliability.

As a result of examination of the improvement of magnetic characteristics of a medium formed by a room temperature process, the present inventor has found that there is a close relationship between the surface resistivity of a medium and magnetic characteristics, so that magnetic characteristics can be improved by reducing the surface resistivity. Thus, the present invention has been achieved.

As described above, since a granular magnetic layer and an under layer comprising a metal or an alloy are used in a medium, the surface resistivity of the medium substantially represents the resistance of the under layer, which is thought to show the crystallizability and elaborateness of the under layer. That is, it has been found that high magnetic characteristics can be stably realized by controlling the crystallizability and elaborateness of the under layer with the surface resistivity.

In particular, in a case of using a polymer resin support and a flexible polymer film support that are lowered in magnetic characteristics, the surface resistivity conspicuously increases. This is presumably due to the fact that the gas contained in the polymer resin support and the flexible polymer film support is taken into the under layer at the time of forming the film. That is, it is presumed that the crystallizability of the under layer deteriorates by forming the under layer in a state of retaining the gas contained in the support in a room temperature process, which results in a magnetic recording medium having high surface resistivity. It has been found, therefore, that a magnetic recording medium having low surface resistivity and high magnetic characteristics can be obtained by forming an under layer and a magnetic layer by introducing rare gas to a desired pressure after adjusting the degree of vacuum and the partial pressure of water to prescribed levels in a film forming chamber holding the support.

Further, when an under layer and a magnetic layer are continuously formed on a flexible polymer film support wound on a reel, gas is always discharged from the rolled film. Accordingly, a magnetic recording medium having low surface resistivity and high magnetic characteristics can be obtained by forming an under layer and a magnetic layer in the same manner as above after performing degasification treatment beforehand and adjusting the degree of vacuum and the partial pressure of water to prescribed levels while transporting the film support.

The invention is as follows.

(1) A magnetic recording medium comprising a support having provided at least on one side of the support an under layer comprising at least a metal or an alloy and a granular magnetic layer comprising ferromagnetic metal particles and a nonmagnetic oxide, wherein the surface resistivity of the medium is in the range of from 1 to 100 Ω/□.

(2) The magnetic recording medium as described in the above item (1), wherein the under layer and the granular magnetic layer are provided by a vacuum deposition method.

(3) The magnetic recording medium as described in the above item (1) or (2), wherein the surface resistivity is in the range of from 1 to 50 Ω/□.

(4) The magnetic recording medium as described in the item (1), (2) or (3), wherein the under layer contains at least one element selected from Cr, Ti, Ru, Re and Pt.

(5) The magnetic recording medium as described in the item (1), (2), (3) or (4), wherein the under layer comprises Ru or an Ru alloy.

(6) The magnetic recording medium as described in any of the items (1) to (5), wherein the thickness of the under layer is 50 nm or less.

(7) The magnetic recording medium as described in any of the items (1) to (6), wherein the support is a flexible polymer support.

(8) A manufacturing method of the magnetic recording medium described in the item (2) comprising processes of introducing rare gas to desired pressure after satisfying the following conditions (1) and (2) in a vacuum film-forming apparatus, and then forming the under layer and the granular magnetic layer described in the item (1) on a support introduced into the vacuum film-forming apparatus:
Vacuum degree≦1×10⁻⁴ Pa (1)
Partial pressure of water≦7×10⁻⁵ Pa (2)

(9) The manufacturing method of a magnetic recording medium as described in the item (8), wherein the temperature of the support at the time of forming the under layer and the granular magnetic layer is less than 80° C.

(10) The manufacturing method of a magnetic recording medium described in the item (8) or (9), wherein the support is a flexible polymer support fed in a rolled form, and the method comprises processes of unwinding the support from an unwinding roller in a vacuum film-forming apparatus, forming at least the under layer and the granular magnetic layer in a film-forming chamber while the flexible polymer support is transported, and winding the resulting magnetic recording medium with a winding roller.

According to the invention, a high density magnetic recording medium can be manufactured inexpensively with an under layer and a magnetic layer capable of forming at room temperature. The magnetic recording medium according to the invention is not restricted to a hard disc and rigid polymer resin supports and flexible polymer film supports can be used, therefore, the range of application of the magnetic recording medium of the invention widens to inexpensive hard discs, magnetic tapes, flexible discs, magnetic sheets and the like.

### BRIEF DESCRIPTION OF THE DRAWINGS

FIG. 1 is a drawing showing an example of a vacuum film forming apparatus for use in the invention.

### DETAILED DESCRIPTION OF THE INVENTION

The mode for carrying out the invention will be described in detail with reference to the accompanying drawing.

As the support of the magnetic recording medium in the invention, an A1 support, a glass support, and an injection molded polymer resin support can be used, but it is more preferred to use a flexible polymer film support in the point of productivity. A tape-like support and a flexible disc-like support can be used in the invention. A flexible disc in the invention using a flexible polymer film support takes a structure having a center hole formed at the central part, which is encased in a cartridge formed of plastic and the like. The cartridge is generally equipped with an access window covered with a metal shutter, and recording of signals on the flexible disc and reproduction are carried out by the introduction of a magnetic head through the access window.

A flexible disc in the invention generally comprises a disc-like support comprising a flexible polymer film having on each of both sides thereof at least an under layer and a magnetic layer. It is preferred that the flexible disc is composed of an undercoat layer for improving a surface property and a gas barrier property, a barrier layer having functions such as adhesion and gas barrier, a seed layer for controlling the crystal orientation of an under layer, an under layer, a magnetic layer, a protective layer for protecting the magnetic layer from corrosion and abrasion, and a lubricating layer for improving running durability and corrosion resistance laminated in this order.

As the flexible polymer film supports, resin films comprising aromatic polyimide, aromatic polyamide, aromatic polyamideimide, polyether ketone, polyether sulfone, polyether imide, polysulfone, polyphenylene sulfide, polyethylene naphthalate, polyethylene terephthalate, polycarbonate, triacetate cellulose, or fluorine resin are exemplified. Since good recording characteristics can be achieved without heating a support in the invention, polyethylene terephthalate and polyethylene naphthalate are especially preferred in view of costs and surface properties.

The thickness of the polymer film is from 3 to 200 μm, and in a case of a flexible disc, the thickness is preferably from 20 to 100 μm, and more preferably from 20 to 60 μm. In a case of a magnetic tape, the thickness is preferably from 3 to 15 μm, and more preferably from 4 to 12 μm.

In a case of a flexible polymer film support, it is preferred to provide an undercoat layer on the surface of the support for the purpose of the improvement of flatness and gas barrier. For forming a magnetic layer by sputtering and the like, it is preferred that the undercoat layer is excellent in heat resistance. As the materials of the undercoat layer, e.g., a polyimide resin, a polyamideimide resin, a silicone resin, a fluorine resin, etc., can be used. A thermosetting polyimide resin and a thermosetting silicone resin are high in smoothing effect and especially preferred. The thickness of the undercoat layer is preferably from 0.1 to 3.0 μm. When other resin film is laminated on a support, an undercoat layer may be formed before lamination processing, or an undercoat layer may be formed after lamination processing.

In a case of a flexible medium, both in disc-like and tape-like media, a magnetic head and a medium are slid in contact, so that it is preferred to provide minute spines (texture) on the surface of an undercoat layer for the purpose of reducing the true contact area of a magnetic head and a medium and improving a sliding property. Further, a handling property of a support is improved by providing minute spines. In order to form minute spines, a method of coating spherical silica particles and a method of coating an emulsion to thereby form spines of an organic substance can be used, and it is preferred to form minute spines by coating spherical silica particles for ensuring the heat resistance of an undercoat layer.

The height of the minute spines is preferably from 5 to 60 nm, and more preferably from 10 to 30 nm. When the height of the minute spines is too high, the recording and reproducing characteristics of signals are deteriorated due to the spacing loss between the head and the medium, while when the height of the minute spines is too low, a sliding property cannot be improved sufficiently. The density of the minute spines is preferably from 0.1 to 100/μm², and more preferably from 1 to 10/μm². When the density of the minute spines is too low, the improving effect of a sliding property decreases, while when the density is too high, high spines increase by the increase of agglomerated particles, and recording and reproducing characteristics are degraded.

Further, it is also possible to fix minute spines on the surface of a support with a binder. It is preferred to use resins having sufficient heat resistance as the binder. As the resins having heat resistance, solvent-soluble polyimide resins, thermosetting polyimide resins and thermosetting silicone resins are especially preferably used.

As the supports of hard discs, polycarbonate, amorphous polyolefin, glass and aluminum supports can be used.

In a case of hard discs, the thickness of a support is preferably from 0.1 to 2 mm, and more preferably from 0.3 to 1.5 mm.

In a case of hard discs, a magnetic head slightly floats from the surface of a disc and recording is done by non-contact magnetic recording system, so that the surface of a support is preferably smooth. Ra measured with AFM is preferably 1 nm or less, and more preferably 0.8 nm or less. For reducing the frictional force of the time when a magnetic head is in contact with a disc, surface roughness called texture may be provided by a physicochemical polishing method.

A barrier layer is preferably provided for purposes of restraining gas from being discharged from a support and improving adhesion. As such a barrier layer, nonmetallic elements alone or mixtures thereof, or compounds of Ti and nonmetallic elements can be used.

The thickness of a gas barrier layer is preferably from 2 to 200 nm, and especially preferably from 5 to 100 nm. When the thickness is greater than this range, productivity lowers and noise increases due to thickening of crystal particles, while when smaller than this range, gas barrier effect cannot be obtained.

It is preferred to provide a seed layer just under an under layer for purposes of the improvement of the crystal orientation of the under layer and the provision of electric conductivity. As such a seed layer, Ti, W and Ni alloys are preferably used, but other alloys may be used.

The thickness of a seed layer is preferably from 1 to 30 nm. When the thickness is greater than this range, productivity lowers and noise increases due to thickening of crystal particles, while when smaller than this range, a seed layer effect cannot be obtained.

It is preferred in the invention that an under layer is formed of the materials capable of controlling the crystal orientation of the magnetic layer just above. As such an under layer, metals or alloys containing at least one element selected from Cr, Ti, Ru, Re and Pt are preferably used, and Ru or an Ru alloy is more preferred.

The thickness of an under layer is preferably from 3 to 200 nm, more preferably from 5 to 100 nm, and still more preferably from 5 to 50 nm. When the thickness is greater than this range, productivity lowers and noise increases due to thickening of crystal particles, while when smaller than this range, the improvement of magnetic characteristics by an under layer effect cannot be obtained.

As a sputtering method for forming an under layer, any of well-known DC sputtering methods and RF sputtering methods can be used. General argon gases can be used as the gas in sputtering of an under layer but other rare gases can also be used. When gas pressure is low in sputtering an under layer, the under layer can obtain elaborate and high crystallizability. However, the gas pressure in sputtering an under layer strongly influences the crystal orientation of the under layer in some cases. In particular, in a case where Ru or an Ru alloy is used in an under layer, the c axis of an hcp structure is liable to be perpendicularly oriented if sputtering gas pressure is low, and the c axis is liable to be oriented in the in-plane direction if sputtering gas pressure is high. Accordingly, the gas pressure in sputtering an under layer is preferably from 0.1 to 1.5 Pa in a case of perpendicular orientation, and preferably from 2.0 to 10.0 Pa in a case of in-plane orientation.

A magnetic layer may be an in-plane magnetic recording layer having the axis of easy magnetization oriented in the horizontal direction to the support or may be a perpendicular magnetic recording layer oriented in the perpendicular direction to the support. The direction of the axis of easy magnetization can be controlled by the material and film forming condition of an under layer and the composition and film forming condition of a magnetic layer.

A magnetic layer in the invention is a granular magnetic layer comprising a ferromagnetic metal alloy and a nonmagnetic oxide as described above. By the addition of a nonmagnetic oxide hardly solid soluble with ferromagnetic metal alloy particles to the ferromagnetic metal alloy particles, the granular magnetic layer takes a structure such that the ferromagnetic metal alloy particles are isolated by the nonmagnetic oxide even when the layer is formed at room temperature, and the particle size of the ferromagnetic metal alloy particles is from 1 to 20 nm or so. By taking such a structure, a high coercive force can be achieved and the particle size dispersion of the magnetic particles is uniform, so that a low noise medium can be obtained.

As ferromagnetic metal alloys, alloys comprising Co, Cr, Pt with elements, e.g., Ni, Fe, B, Si, Ta, Nb and Ru can be used, and Co—Pt—Cr, Co—Pt—Cr—Ta, Co—Pt—Cr—B and Co—Ru—Cr are especially preferred considering recording characteristics.

As nonmagnetic oxides, oxides of Si, Zr, Ta, B, Ti, Al, Cr, Ba, Zn, Na, La, In and Pb can be used, and SiOₓ is most preferred considering recording characteristics.

The mixing ratio (molar ratio) of ferromagnetic metal alloy/nonmagnetic oxide is preferably from 95/5 to 80/20, and particularly preferably from 90/10 to 85/15. By adjusting the mixing ratio as above, the segregation among magnetic particles is sufficient and the coercive force is ensured, in addition, a high signal output can be obtained, since the amount of magnetization is secured.

The thickness of a granular magnetic layer is preferably from 5 to 60 nm, and more preferably from 5 to 30 nm. When the thickness is in this range, output can be secured by the reduction of noise and the restraint of the influence of thermal fluctuation, the resistance to the stress applied at the time of head-medium contact can be ensured, and running durability can be assured.

Sputtering methods capable of forming a high quality and hyper thin film with ease are preferably used in the invention as methods for forming a granular magnetic layer, and any of well-known DC sputtering method, DC pulse sputtering method, and RF sputtering method can be used. General argon gases can be used as the sputtering gas in sputtering a magnetic layer but other rare gases can also be used. For accelerating the segregation of ferromagnetic metal alloy particles, or for adjusting the oxygen content of a nonmagnetic oxide, a trace amount of oxygen gas may be introduced. Gas pressure at the time of the sputtering of a granular magnetic layer influences the segregation and the crystallizability of ferromagnetic metal particles. When the gas pressure is high, the segregation of magnetic particles is expedited and magnetic interaction can be restrained, but the crystallizability of magnetic particles is low, which results in the reduction of Hc and Mr. On the other hand, when the gas pressure is low, the crystallizability of magnetic particles is improved and Hc and Mr are heightened, but the resulting layer is great in magnetic interaction. Accordingly, the gas pressure is preferably from 1.0 to 10 Pa, and more preferably from 1.5 to 8.0 Pa.

For forming a granular magnetic layer by a sputtering method, it is possible to use two kinds of a ferromagnetic metal alloy target and a nonmagnetic oxide target and use a co-sputtering method of these two targets. However, for the purpose of improving magnetic particle size dispersion to thereby form a uniform film, it is preferred to use an alloy target of a ferromagnetic metal alloy and a nonmagnetic oxide. The alloy target can be manufactured by a hot press method.

It is preferred to provide a protective layer on a magnetic layer. A protective layer is provided for preventing the corrosion of metallic materials contained in a magnetic layer, and preventing the abrasion of a magnetic layer by the pseudo contact or contact sliding of a magnetic head and a magnetic disc to thereby improve running durability and anticorrosion. Materials such as oxides, e.g., silica, alumina, titania, zirconia, cobalt oxide and nickel oxide, nitrides, e.g., titanium nitride, silicon nitride and boron nitride, carbides, e.g., silicon carbide, chromium carbide and boron carbide, graphite and amorphous carbon can be used in a protective layer.

A protective layer is a hard film having hardness equal to or higher than the hardness of the material of a magnetic head, and materials that hardly cause burning during sliding and stably maintain the effect are preferred, since such hard films are excellent in tribological durability. At the same time, materials having fewer pinholes are excellent in anticorrosion and preferred. As such a protective layer, hard carbon films called DLC (diamond-like carbon) manufactured by a plasma CVD method, an ion beam method or an ECR sputtering method are exemplified.

A protective layer may be formed by the lamination of two or more kinds of thin films having different properties. For example, it becomes possible to reconcile anticorrosion and durability on a high level by providing a hard carbon protective layer on the surface side for improving a tribological property and a nitride protective layer, e.g., silicon nitride, on the magnetic recording layer side for improving anticorrosion.

A lubricating layer is provided on a protective layer for the purpose of improving running durability and anticorrosion. Lubricants, e.g., well-known hydrocarbon lubricants, fluorine lubricants and extreme pressure additives, are used in a lubricating layer.

As hydrocarbon lubricants, carboxylic acids, e.g., stearic acid and oleic acid, esters, e.g., butyl stearate, sulfonic acids, e.g., octadecylsulfonic acid, phosphoric esters, e.g., monooctadecyl phosphate, alcohols, e.g., stearyl alcohol and oleyl alcohol, carboxylic acid amides, e.g., stearic acid amide, and amines, e.g., stearylamine, are exemplified.

The examples of fluorine lubricants include lubricants obtained by substituting a part or all of the alkyl groups of the above hydrocarbon lubricants with fluoroalkyl groups or perfluoropolyether groups. The examples of perfluoro-polyether groups include a perfluoromethylene oxide polymer, a perfluoroethylene oxide polymer, a perfluoro-n-propylene oxide polymer [(CF₂CF₂CF₂O)ₙ], a perfluoroisopropylene oxide polymer {([CF(CF₃)CF₂O]ₙ}, and copolymers of these polymers. Specifically, a perfluoromethylene-perfluoroethylene copolymer having hydroxyl groups at molecular chain terminals (FOMBLIN Z-DOL, trade name, manufactured by AUSIMONT K.K. ) is exemplified.

As extreme pressure additives, phosphoric esters, e.g., trilauryl phosphate, phosphorous esters, e.g., trilauryl phosphite, and sulfur extreme pressure additives, such as thiophosphorous esters, e.g., trilauryl trithiophosphite, thiophosphoric esters, and dibenzyl disulfide are exemplified.

These lubricants can be used alone or a plurality of lubricants can be used in combination. A lubricating layer can be formed by coating a solution obtained by dissolving a lubricant in an organic solvent on the surface of a protective layer by spin coating, wire bar coating, gravure coating or dip coating, alternatively by depositing a lubricant on the surface of a protective layer by vacuum evaporation. The coating amount of a lubricant is preferably from 1 to 30 mg/m², and especially preferably from 2 to 20 mg/m².

It is preferred to use rust preventives in combination with a lubricant for bettering anticorrosion. As the examples of rust preventives, nitrogen-containing heterocyclic rings, e.g., benzotriazole, benzimidazole, purine and pyrimidine, derivatives obtained by introducing alkyl side chains to the mother nuclei of these nitrogen-containing heterocyclic rings, nitrogen- and sulfur-containing heterocyclic rings, e.g., benzothiazole, 2-mercaptobenzothiazole, tetraazaindene ring compounds and thiouracil compounds, and derivatives of these heterocyclic rings are exemplified. A rust preventive may be mixed with a lubricant and coated on a protective layer, alternatively a rust preventive may be coated on a protective layer prior to the coating of a lubricant, and then a lubricant may be coated thereon. The coating amount of rust preventives is preferably from 0.1 to 10 mg/m², and especially preferably from 0.5 to 5 mg/m².

The thus-formed magnetic recording medium in the invention has surface resistivity, i.e., surface sheet resistance, of from 1 to 100 Ω/□, and preferably from 1 to 50 Ω/□. The surface resistivity is measured with a four probe method of the surface resistivity measuring instrument.

In the invention, as the vacuum deposition systems for forming an under layer and a magnetic layer, a batch sputtering system and an in-line sputtering system as used in the manufacture of a hard disc support, and a web sputtering system for use in the manufacture of a flexible polymer support can be used.

The web sputtering system for a flexible polymer support is composed of a vacuum chamber, an exhaust means for evacuation thereof, a transporting means for transporting a film wound on a reel, and a means of electric discharge for forming an under layer and a magnetic layer on a support. In the apparatus, a rolled up flexible support is unwound from an unwinding roller, desired films of an under layer and a magnetic layer are formed on a can drum, and the support is wound with a winding roller.

As described above, for reducing the surface resistivity of an under layer, improving the crystallizability of an under layer and enhancing magnetic characteristics, it is important to restrain the gas contained in a support before an under layer is formed with the apparatus.

For that sake, in a case of a vacuum deposition apparatus for a hard disc support, as the pretreatment of discharge of the gas contained in a support after the support is introduced into the vacuum deposition apparatus, it is preferred to perform any one, and more preferably all, of heating of a support at less than 80° C., RF reverse sputtering, and preparation of the above-described barrier layer. Heating of a support and RF reverse sputtering are both preferred for discharging the gas contained in a support, since heat is applied to a support, but excessive treatments give heat damages to the support and productivity also lowers. Therefore, heating temperature is preferably less than 80° C., and more preferably less than 60° C. Electric power to be charged in RF reverse sputtering is preferably less than 1,000 W, and more preferably less than 500 W. That is, it is preferred for a vacuum deposition apparatus for a hard disc support to be provided with the equipment capable of carrying out these pretreatments, by which vacuum degree and partial pressure of water in the vacuum deposition apparatus can be reduced as the conditions before preparation of an under layer. Vacuum degree at this time is 1×10⁻⁴ Pa or less, and preferably 5.0×10⁻⁵ Pa or less. Partial pressure of water is 7×10⁻⁵ Pa or less, and preferably 5.0×10⁻⁵ Pa or less. After satisfying these conditions, by introducing rare gas to desired pressure and forming an under layer, the gas discharged from the support can be prevented from being taken into the under layer, so that magnetic characteristics can be improved.

In a case of a vacuum deposition apparatus for a flexible polymer support, as the pretreatment of discharge of the gas contained in a flexible polymer support unwound from an unwinding roller, it is preferred to perform any one, and more preferably all, of transportation of a flexible polymer support in a vacuum, heating of a support at less than 80° C., RF reverse sputtering, and preparation of the above-described barrier layer. Of these, transportation in a vacuum is preferably performed at vacuum degree of 1.0×10⁻³ Pa or less, and more preferably at 1.0×10⁻⁴ Pa or less. The heating of a support is preferably performed at less than 80° C., and more preferably at less than 60° C. Electric power to be charged in RF reverse sputtering is preferably less than 1,000 W, and more preferably less than 500 W. That is, it is preferred for a vacuum deposition apparatus for a flexible polymer support to be provided with the equipment capable of carrying out these pretreatments, by which vacuum degree and partial pressure of water in the vacuum deposition apparatus can be reduced as the conditions before preparation of an under layer after transportation of a support. Vacuum degree and partial pressure of water at this time are the same as those in the case of the vacuum deposition apparatus for a hard disc support. After satisfying these conditions, by introducing rare gas to desired pressure and forming an under layer, the gas discharged from the support can be prevented from being taken into the under layer, so that magnetic characteristics can be improved.

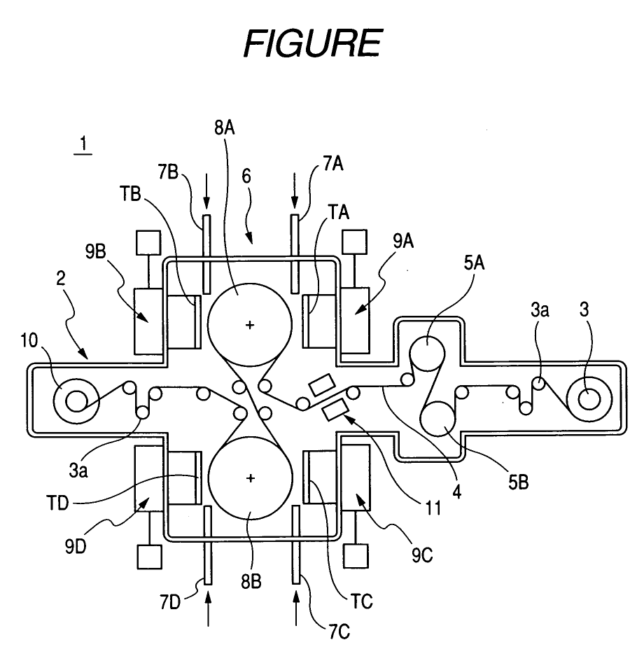

A vacuum film forming apparatus (vacuum deposition apparatus) for a flexible polymer support is shown in FIG. 1.

In FIG. 1, vacuum deposition apparatus 1 is provided with vacuum chamber 2. Support 4 unwound from unwinding roller 3 is delivered to film-forming chamber 6 after the tensile force is adjusted by pass roller 3a, tensile force-adjusting rollers 5A and 5B. Tensile force-adjusting rollers 5A and 5B have a function of heating rollers, and heat a support at a prescribed temperature.

Film-forming chamber 6 is fed with rare gas at a prescribed flow rate through sputtering gas-feeding pipes 7A, 7B, 7C and 7D after the conditions of vacuum degree and partial pressure of water are secured with an exhaust means such as a vacuum pump. While transporting flexible polymer support 4 with winding around film-forming roller 8A provided in film-forming chamber 6, the atoms for forming an under layer spring out from target TA of under layer-sputtering apparatus 9A, and an under layer is formed on the support.

Support 4 is surface treated with RF reverse sputtering (RF ion bombardment) 11 before film forming.

In the next place, on the above-formed under layer at film-forming roller 8A, the atoms for forming a magnetic layer are released from target TB set up on magnetic layer sputtering apparatus 9B, and a magnetic layer is formed on the under layer. Subsequently, while transporting the support with winding the side having provided with the magnetic layer around film forming roller 8B, the atoms for forming an under layer spring out from target TC of under layer sputtering apparatus 9C, and an under layer is formed on the side opposite to the side on which the magnetic layer is provided of the support. Further, at film forming roller 8B, the atoms for forming a magnetic layer are released from target TD set up on magnetic layer sputtering apparatus 9D, and a magnetic layer is formed on the under layer.

Magnetic layers are provided on both sides of the support by the above process, and the support is wound-up by wind-up roller 10 via pass roller 3a.

Incidentally, the invention is not limited to one shown in FIG. 1, and the film-forming process may comprise a process of forming a film on one side of a support in a vacuum chamber having one film-forming roller, and then reversing the support and forming a film on the other side.

Film-forming rollers for use in a vacuum deposition apparatus in the invention are preferably large to a certain degree for holding a support close to the rollers to thereby prevent deviation by transportation, or for opposing a support almost exactly to a sputtering source, and the diameter of the rollers is at least 250 mm or more, and preferably 400 mm or more.

The transportation rate of a support is preferably from 1 cm/minute to 10 m/minute, and more preferably from 10 cm/minute to 8 m/minute. When the transportation rate is not faster than 1 cm/minute, productivity is inferior, and when it is faster than 10 m/minute, it is feared that the influence by deviation of the support due to transportation cannot be negligible.

It is more preferred that a support is passed through a heating and degassing process of heating the support and discharging the gas contained in the support with a heater or a heating roller before layers such as a magnetic layer and the like are formed on the support. It is preferred to provide the heater or the heating roller between the unwinding roller and the film-forming rollers, but the film-forming rollers may be substituted for the heating roller.

### EXAMPLES

The invention will be described with reference to the specific examples, but the invention is not limited thereto.

### Example 1

An undercoat layer coating solution comprising 3-glycidoxypropyltrimethoxysilane, phenyltriethoxysilane, hydrochloric acid, aluminum acetylacetonate and ethanol was coated on a polyethylene naphthalate film having a thickness of 53 μm and surface roughness (Ra) of 1.4 nm by gravure coating, and the coated solution was subjected to drying and curing at 100° C., whereby an undercoat layer having a thickness of 1.0 μm comprising a silicone resin was formed. A mixed coating solution comprising silica sol having a particle size of 25 nm and the above undercoat layer coating solution was coated on the undercoat layer by gravure coating, whereby spines having a height of 15 nm were formed on the undercoat layer in density of 10/μm². The undercoat layer was formed on both sides of the support film. The web was mounted on the web sputtering apparatus shown in FIG. 1, heated at 60° C. with a heating roller, and then subjected to RF ion bombardment at 300 W as pretreatments. After that, Ar was let flow to 3.5 Pa on the conditions of vacuum degree of 7.0×10⁻⁵ Pa and partial pressure of water of 4.0×10⁻⁵ Pa, in the state of holding the web close to a can cooled with water, an under layer comprising Ru having a thickness of 20 nm was formed by a DC magnetron sputtering method, and then a magnetic layer comprising (Co₇₀—Pt₂₀—Cr₁₀)₈₈—(SiO₂)₁₂ having a thickness of 20 nm was formed by a DC magnetron sputtering method. These under layer and magnetic layer were formed on both sides of the film. In the next place, the web was mounted on a web type protective layer forming apparatus, and a nitrogen added DLC protective layer comprising C/H/N of 62/29/7 in molar ratio and having a thickness of 5 nm was formed according to an ion beam deposition process using ethylene gas, nitrogen gas and argon gas as reaction gases. The protective layer was also provided on both sides of the film. Subsequently, a lubricating layer having a thickness of 1 nm was formed on the surface of the protective layer by coating a solution obtained by dissolving a perfluoropolyether lubricant having hydroxyl groups at the molecule terminals (FOMBLIN Z-DOL, manufactured by Ausimont K.K.) in a fluorine lubricant (HFE-7200, manufactured by Sumitomo 3M Limited) by gravure coating. The lubricating layer was also formed on both sides of the film. A 3.7 inch size disc was punched out of the web, subjected to tape burnishing treatment, and built into a resin cartridge (for Zip 100, manufactured by Fuji Photo Film Co., Ltd.), whereby a flexible disc was obtained.

### Example 2

A flexible disc was manufactured in the same manner as in Example 1, except that a barrier layer comprising C was formed on the conditions of 0.13 Pa and a thickness of 20 nm before forming an under layer comprising Ru.

### Example 3

A flexible disc was manufactured in the same manner as in Example 1, except that pretreatment of transportation in a vacuum on the condition of 5.0×10⁻⁵ Pa was added.

### Example 4

In Example 1, PEN having a thickness of 9 μm was used as a support, and the web was slit in a width of 8 mm after coating a lubricant, whereby a magnetic tape was obtained.

### Example 5

A flexible disc was manufactured in the same manner as in Example 1, except that an under layer comprising Cr was formed on the condition of 1.0 Pa.

### Example 6

A specularly polished 2.5 inch glass support was introduced into a vacuum deposition apparatus for a hard disc support, heated at 60° C. with a heater and then subjected to RF reverse sputtering at 200 W as pretreatments. Subsequently, an under layer comprising Ru and a magnetic layer comprising CoPtCr—SiO₂ were formed on the same conditions as in Example 1. Further, a DLC protective layer was formed and a lubricant was coated, whereby a hard disc was obtained.

### Example 7

A hard disc was manufactured in the same manner as in Example 6, except that a barrier layer comprising C was formed on the conditions of 0.13 Pa and a thickness of 20 nm before forming an under layer comprising Ru.

### Example 8

A hard disc was manufactured in the same manner as in Example 6, except that polycarbonate was used as a support.

### Example 9

A flexible disc was manufactured in the same manner as in Example 2, except that a gas barrier layer comprising C was formed on the conditions of 0.13 Pa and a thickness of 20 nm without being subjected to heating, and then an under layer comprising Ru was formed.

### Example 10

A hard disc was manufactured in the same manner as in Example 8, except that a gas barrier layer comprising C was formed on the conditions of 0.13 Pa and a thickness of 20 nm without being subjected to heating, and then an under layer comprising Ru was formed.

### Comparative Example 1

A flexible disc was manufactured in the same manner as in Example 1, except that an under layer was formed on the conditions of vacuum degree of 3.0×10⁻⁴ Pa and partial pressure of water of 1.5×10⁻⁴ Pa without being subjected to pretreatment.

### Comparative Example 2

A hard disc was manufactured in the same manner as in Example 5, except that an under layer was formed on the conditions of vacuum degree of 3.0×10⁻⁴ Pa and partial pressure of water of 1.5×10⁻⁴ Pa without being subjected to pretreatment.

The performances of each of the obtained samples were evaluated as follows, and the results are shown in Table 1 below.

Methods of Evaluations:

1) Magnetic characteristics

Coercive force Hc was measured with VSM.
2) Surface resistivity (surface sheet resistance)

Surface resistivity was measured with a four probe method of the surface resistivity measuring instrument.
3) Deformation of support

Each magnetic recording medium was visually observed and the presence or absence of wrinkles, streaks and waviness was evaluated according to the following criteria.

o: Wrinkles, streaks and waviness were not observed.

x: Wrinkles, streaks and waviness were observed.

TABLE 1

| | | Surface | |
|---|---|---|---|
| | Hc | Resistivity | Support |
| Example No. | (kA/m) | (Ω/□) | Deformation |
| Example 1 | 247 | 77 | ∘ |
| Example 2 | 263 | 23 | ∘ |
| Example 3 | 251 | 67 | ∘ |
| Example 4 | 255 | 64 | ∘ |
| Example 5 | 231 | 26 | ∘ |
| Example 6 | 265 | 21 | ∘ |
| Example 7 | 268 | 19 | ∘ |
| Example 8 | 248 | 74 | ∘ |
| Example 9 | 260 | 28 | ∘ |
| Example 10 | 265 | 22 | ∘ |
| Comparative | 212 | 138 | ∘ |
| Example 1 | | | |
| Comparative | 231 | 106 | ∘ |
| Example 2 | | | |

As can be seen from the results, the flexible discs and hard discs in the invention achieved high magnetic characteristics, although they were manufactured according to a room temperature process. On the other hand, samples in Comparative Examples 1 and 2 were low in magnetic characteristics as compared with the samples in the invention, since the surface resistivity was high for the reasons that pretreatments were not performed and the controls of the vacuum degree and the partial pressure of water were insufficient.

This application is based on Japanese Patent application JP2005-106382, filed Apr. 1, 2005, the entire content of which is hereby incorporated by reference, the same as if set forth at length.

What is claimed is:

1. A magnetic recording medium comprising:
a support;
an under layer comprising at least one of a metal and an alloy; and
a granular magnetic layer comprising ferromagnetic metal particles and a nonmagnetic oxide,
wherein the magnetic recording medium has a surface resistivity of from 1 to 100 Ω/□.

2. The magnetic recording medium as claimed in claim 1, wherein the under layer and the granular magnetic layer are provided by a vacuum deposition method.

3. The magnetic recording medium as claimed in claim 1, wherein the surface resistivity is from 1 to 50 Ω/□.

4. The magnetic recording medium as claimed in claim 1, wherein the under layer comprises at least one element selected from Cr, Ti, Ru, Re and Pt.

5. The magnetic recording medium as claimed in claim 1, wherein the under layer comprises Ru or an Ru alloy.

6. The magnetic recording medium as claimed in claim 1, wherein the under layer has a thickness of 50 nm or less.

7. The magnetic recording medium as claimed in claim 1, wherein the support is a flexible polymer support.

8. The magnetic recording medium as claimed in claim 2, wherein the vacuum deposition method comprises:
introducing rare gas into a vacuum deposition apparatus after satisfying that a vacuum degree in the vacuum deposition apparatus is no more than 1×10⁻⁴ Pa and a partial pressure of water in the vacuum deposition apparatus is no more than 7×10⁻⁵ Pa; and
forming the under layer and the granular magnetic layer over a support introduced into the vacuum film-forming apparatus, after the introducing.

9. The magnetic recording medium as claimed in claim 8, wherein a temperature of the support at the time of forming the under layer and the granular magnetic layer is less than 80° C.

10. A method for manufacturing the magnetic recording medium claimed in claim 2, the method comprising:
introducing rare gas into a vacuum deposition apparatus after satisfying that a vacuum degree in the vacuum deposition apparatus is no more than 1×10⁻⁴ Pa and a partial pressure of water in the vacuum deposition apparatus is no more than 7×10⁻⁵ Pa; and
forming the under layer and the granular magnetic layer over a support introduced into the vacuum film-forming apparatus, after the introducing.

11. The method as claimed in claim 10, wherein a temperature of the support at the time of forming the under layer and the granular magnetic layer is less than 80° C.

12. The method as claimed in claim 10, wherein the support is a flexible polymer support fed in a rolled form, and the method comprises: unwinding the support from an unwinding roller in a vacuum film-forming apparatus; forming at least the under layer and the granular magnetic layer while the flexible support is transported; and winding the resulting magnetic recording medium with a winding roller.
